(19) United States
(12) Patent Application Publication
(10) Pub. No.: US 2026/0278229 A1
(43) Pub. Date: Sep. 17, 2026

(54) METHOD FOR PROVIDING DIE-TO-DIE TESTABILITY

(71) Applicant: Microsoft Technology Licensing, LLC, Redmond, WA (US)

(72) Inventors: Charles Walter BOECKER, Ames, IA (US); Eric Douglas GROEN, Ankeny, IA (US); Terrence Huat Hin TAN, Bayan Lepas (MY); Roxanne VU, San Jose, CA (US); Pradipta Kumar GHOSH, Palo Alto, CA (US); Ravi SHIVNARAINE, Pickering (CA)

(21) Appl. No.: 19/076,017

(22) Filed: Mar. 11, 2025

(51) Int. Cl. G06F 30/333

(52) U.S. Cl. CPC G06F 30/333

(57) ABSTRACT

The technology described herein provides a device including a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer.

### BACKGROUND

System on chip (SoC) may be implemented as an integrated circuit (IC) design that combines many or all high-level function elements of an electronic device onto a single chip instead of using separate components mounted to a motherboard, as is done in traditional electronics design. Modern electronic and computing systems use logic configured SoC architecture generally include a number of dies or chiplets. Before SoC are delivered and deployed in electronic devices a number of calibration methods are used to ensure proper functioning of the SoC.

### SUMMARY

The described technology provides a device including a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

The disclosure will be readily understood by the following detailed description in conjunction with the accompanying drawings, wherein like reference numerals designate like structural elements.

It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

FIG. 1 illustrates an example symmetrical bandwidth implementation of a D2D testing system.

FIG. 2 illustrates an example asymmetrical bandwidth implementation of a chip having a number of Tx macros and Rx macros.

FIG. 3 illustrates an example implementation of an asymmetrical Tx testing system for asymmetrical implementation of Tx and Rx macros.

FIG. 4 illustrates an example implementation of an Rx self-check system for an Rx macro.

FIG. 5 illustrates an example implementation of a chip testing system using an analog to digital (ADC) converter for wafer sorting.

FIG. 6 illustrates a layout of an example wafer using one or more sacrificial pads that can be used for wafer sort.

### DETAILED DESCRIPTIONS

System on chip (SoC) may be implemented as an integrated circuit (IC) design that combines many or all high-level function elements of an electronic device onto a single chip instead of using separate components mounted to a motherboard, as is done in traditional electronics design. Modern electronic and computing systems use logic configured SoC architecture generally include a number of dies or chiplets. Before SoC are delivered and deployed in electronic devices a number of calibration methods are used to ensure proper functioning of the SoC. To ensure proper functioning of the SoC, not only the dies need to be calibrated, but die-to-die communication also needs to be calibrated.

Chips are often arranged on a wafer made of silicon (or other suitable material). A wafer may have multiple chips formed thereupon and the individual chips are diced into separate chips after manufacturing of the wafer with large number of chips thereupon. Wafer sorting is used to determine which of the chips are without manufacturing defects, while they are still part of the wafer and still not packaged into individual chips.

The described technology provides a device including a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer

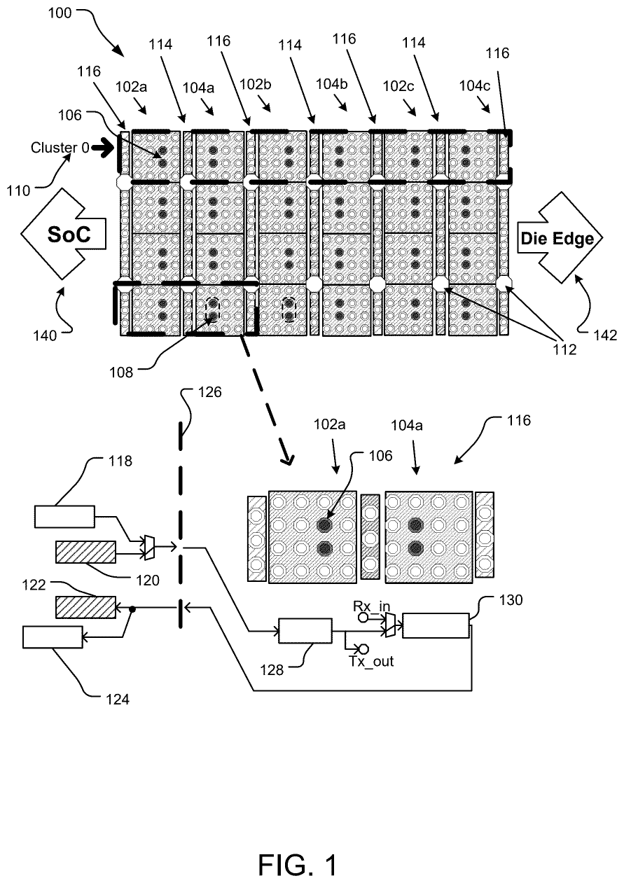

FIG. 1 illustrates a symmetrical bandwidth implementation of a D2D testing system 100. Specifically, the D2D testing system 100 illustrates a symmetrical bandwidth implementation where transmitter (Tx) macros and receiver (Rx) macros are placed close to each other on the chip. Specifically, the D2D testing system 100 includes a number of Tx macros 102 (102a, 102b, 102c) next to a number of Rx macros 104 (104 a, 104 b, 104 c). Each of the Tx macros 102 may include 14 Tx lanes and two Tx clock bumps 106 (illustrated by shaded lanes). Similarly, each of the Rx macros 104 may include 14 Rx lanes and two Rx clock bumps 108 (illustrated by shaded lanes).

Furthermore, the D2D testing system 100 has number of adjacent Tx macros 102 and Rx macros 104 arranged in clusters including clusters. For example, as illustrated a cluster 0 110 includes three Tx macros 102 and three Rx macros 104. In the implementation of the symmetrical bandwidth case as disclosed herein, because the Tx macro 102a and the Rx macro 104a are next to each other, it provides an efficient manner to route the signal from the Tx macro 102a to the Rx macro 104a.

The D2D testing system 100 also includes a number of probe pads, also referred to as sacrificial pads 112 that may be used for power up the macros 102, 104 and to test the macros 102, 104 during wafter sorting. The Tx macros 102 and the Rx macros 104 may be separated by a ground column 114 and power column 116. The D 2D testing system 100 may be connected to an SoC with a parallel input data path 140 coming into the Tx macros 102 and a parallel output data path 122 coming from the Rx macros 104 to the SoC.

When the D2D testing system is configured in analog form, the Tx macros 102 maybe routed to the Rx macros 104 and thus the Tx macros 102 are used as data source. When formed in digital format, the Tx macros 102 may receive input from a normal Tx data path 118 combined with pseudorandom bit sequence (PRBS) generator 120 output. The combined output is input into the Tx 128. In analog loopback mode, the Tx 128 may be routed directly to the Rx 130. For example, the data coming into the Tx 128 may be at 2 GB/sec and the Tx 128 may communicate it to the Rx 130 at 20 GB/sec.

The output from the Rx 130 may be connected to Rx data path 124 and a PRBS check module 122. Specifically, the Rx 130 communicates back to the Rx data path 124 at 2GB/sec. The PRBS check module 122 compares the pattern received from the Rx 130 with the pattern generated by the PRBS generator 120 and if the patterns do not match, the D2D testing system 100 may conclude that there is fault in the chip including the Tx 128 and the Rx 130. In one implementation, the PRBS generator 120 may generate multiple combinations of what functional traffic may look like on the path to the Tx 128 and from Rx 130.

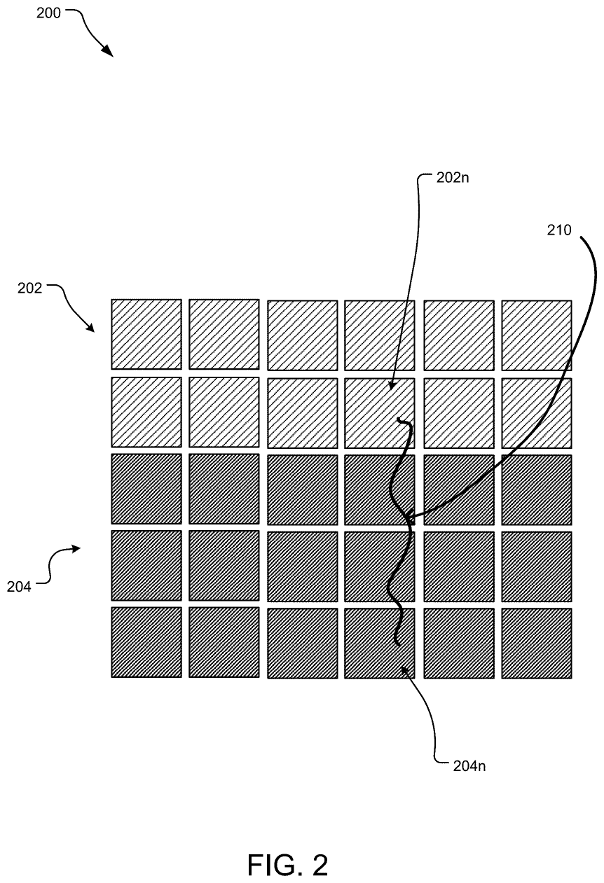

FIG. 2 illustrates an asymmetricalbBandwidth implementation of a chip 200 having a number of Tx macros and Rx macros. Specifically, the chip 200 includes multiple (twelve in this implementation) Tx macros 202 and multiple (eighteen in this implementation) Rx macros 204. Therefore, this asymmetric implementation includes two transmitters in the Tx macro 202 for three Rx in the Rx macro 204. Thus, there is no one to one correspondence between the transmitters and the receivers. Furthermore, as shown, the individual Tx from the Tx macros 202 may not have a direct path to an Rx in the Rx macro 204. For example, for a communication 210 from a Tx 202n to an Rx 204n, there is no easy path to route. Therefore, the routing between the Tx and Rx for wafer sorting may be difficult to develop and to integrate. The technology disclosed herein provides a system and method of wafer sort for such asymmetrical implementation.

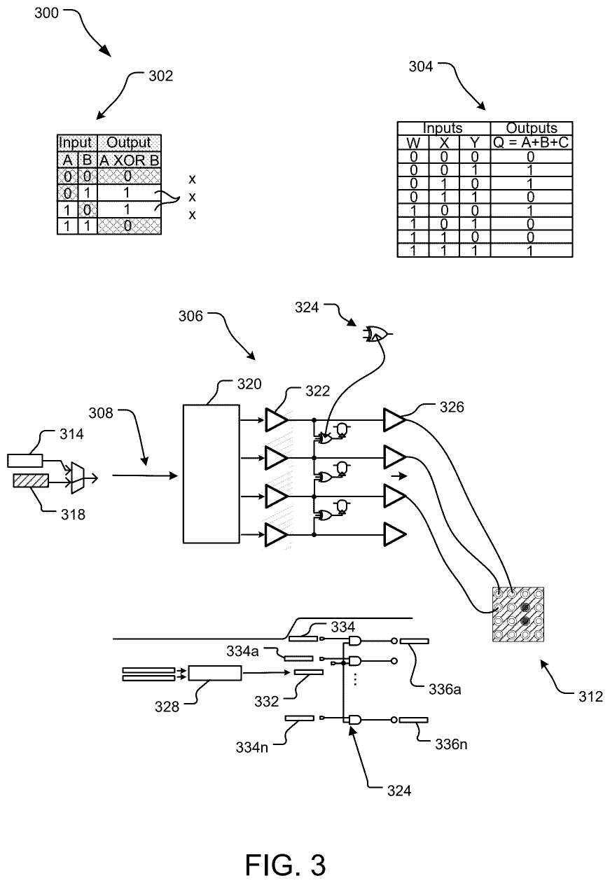

FIG. 3 illustrates an implementation of an asymmetrical Tx testing system 300 for asymmetrical implementation of Tx and Rx macros. For example, the asymmetrical Tx testing system 300 is illustrated as checking one of the Tx macros or an Rx macro illustrated in the asymmetrical bandwidth implementation of a chip 200 having a number of Tx macros and Rx macros as shown in FIG. 2.

Specifically, the asymmetrical Tx testing system 300 illustrates a Tx 306 that receives a combined input 308 from a PRBS generator 318 and a normal Tx data path 314. Specifically, same exact pattern may be sent per bit basis as combined input 308 to each lane of a Tx macro that include the Tx 306. Thus, for example, in a serial manner, all lanes may get one (1) as the first bit, then all the lanes get zero (0) as the next bit, etc.

The combined input 308 passes through a Tx data path 320 and the output is multiplexed to generate pre-driver 2-1 MUX output 322. The outputs from each of the lanes are compared using logic gates 324 with an XOR function. The 2-bit XOR truth table 302 illustrates the outputs of the logic gates 324. On the other hand, the illustrated implementation may have the logic gates 324 with 3-bit XOR function, which as a 3-bit XOR truth table 304 showing the outputs Q for inputs received from three lanes W, X, and Y.

The asymmetrical Tx testing system 300 is illustrated as checking all the lanes of a macro block 312 (which, for example, may be an Tx Macro). As illustrated Tx output drivers 326 couples the outputs from the Tx data path 320 to the one or more lanes of the macro block 312. Thus, the asymmetrical Tx testing system 300 determines if all lanes of the macro block 312 are receiving the same serial pattern of bits (as the serial pattern input into the Tx data path 320. If at least one of the lanes of the macro block 312 receives a pattern that is different than the other lanes, the logic gates 324 generates an error flag that may be sent to a control and status register of the asymmetrical Tx testing system 300.

In one implementation of the asymmetrical Tx testing system 300 using a 3-bit XOR, an error bit 332 may be in inserted together with the input bits 334 (334a, 334b, . . . 334n) into the logic gates 324. This is to ensure that the self-test implemented by the D2D testing system 300 is a valid method. This is further illustrated by a self-test data path 310 which includes an error injection decoder 328 that encodes an error bit 332 that can be inserted together with the input bits 334 (334, 334a, . . . 334n) into the logic gates 324. The outputs 336 (336a . . . 336n) may be used to determine that the asymmetrical Tx testing system 300 is functioning properly. For example, when the error bit 332 is encoded and the output 336 does not indicate an error, it may be an indicator that the implementation of the asymmetrical Tx testing system 300 is incorrect. On the other hand, when the error bit 332 is injected and the output 336 indicates a one (1), the D2D testing system 300 may determine that the asymmetrical Tx testing system 300 is implemented correctly.

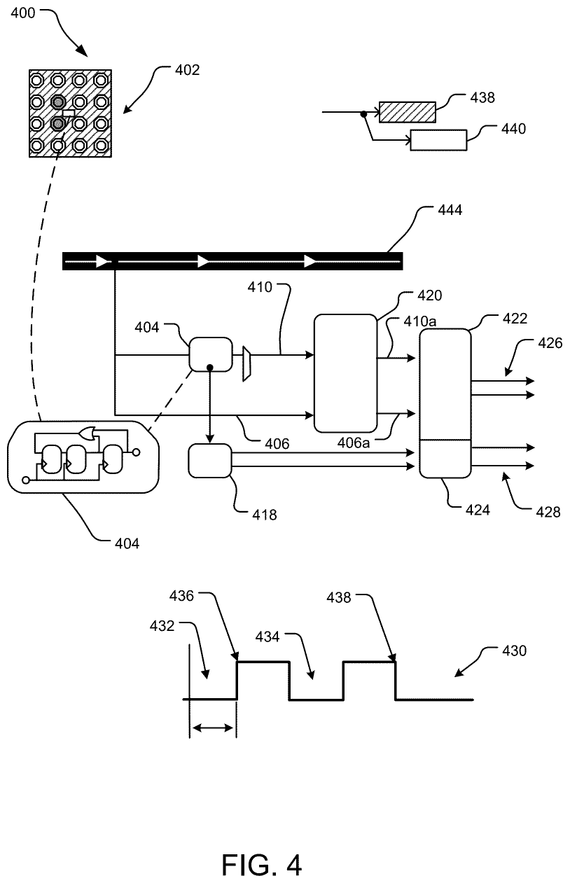

FIG. 4 illustrates an implementation of an Rx self-check system 400 for an Rx macro 402. The Rx self-check system 400 include a PRBS generator 404 that may be configured in each of the macros, such as the Rx macro 402, as a common block. Specifically, the PRBS generator 404 drive all the lanes of the Rx macro 402. In the illustrated implementation, the PRBS generator 404 may override a data-path and drive a pattern into the Rx deserializer 420.

FIG. 4 illustrates an Rx data path 444 of the Rx macro together with the Rx self-check system. A clock signal 406 may be input to PRBS generator 404 as well as into the Rx deserializer 420. The data coming in from the Rx data path 444 may be bypassed through the PRBS data. Therefore, in the test mode, instead of sending normal data from the Rx data path 444 into the Rx deserializer 420, the PRBS generator 404 output 410 is input to the Rx deserializer 420. The output data 410a and the clock signal 406a from the Rx deserializer 420 are input into Rx data path 422. The Rx data path 422 includes an eye path 424 which allows the timing offset and voltage offset to be varied with respect to the normal data path to understand the margin within the system. that receives input from a demultiplexer 418 that demultiplexes the PRBS pattern. The eye path 424 generates a PRBS generator self-test output 428. Whereas the Rx data path 422 generates Rx data path output 426 that can be checked using a PRBS checker 438 when in test mode. When not it the test mode, the Rx data path output 426 is coupled to the normal data output path 440.

FIG. 4 also illustrates the unit interval (UI) method for implementing the PRBS function of the PRBS generator 404. Specifically, the clock signal 430 illustrates a one UI method where each period 432, 434 represents one bit. For example, the one UI method may be implemented at 24 GBps. When using one UI method, the PRBS generator is timed at a positive edge 436 and a negative edge 438 of the clock signal 430, which allows exercising the Rx data path at full rate. Alternatively, the Rx data path may be exercised at only even bits, also referred to as the even data path or at the rising edge of the clock signal 430. Here the PRBS generator is timed at only the rising edge of the clock signal 430. Yet alternatively, the Rx data path may be exercised at only odd bits, also referred to as the odd data path or at the falling edge of the clock signal 430. Each of the even data path and the odd data path methods use two UIs.

In one implementation of the Rx self-check system 400, the even data path method is used for one instance of Rx self-check test and then the clock is changed to use the negative edge for an odd data path method for the subsequent instance of Rx self-check test. Implementing the Rx self-check system 400 with one instance to use even data path method at the positive edge of the clock signal 320 and another instance to use odd data path method at the negative edge of the clock signal 320 provides an easier implementation of the Rx self-check system 400.

In one implementation, wafer sorting may use both the Tx macro check using the Tx testing system 300 and an Rx macro check using the Rx self-check system 400. For example, both the Tx macro check and the Rx macro check may be performed in parallel and if both of them pass, the wafer sorting indicates no manufacturing defects. However, if either of them fails, it indicates that at least one or more than one, lane of the Rx macros and/or the Tx macros on the wafer has a manufacturing defect. As a result, the wafer may be discarded.

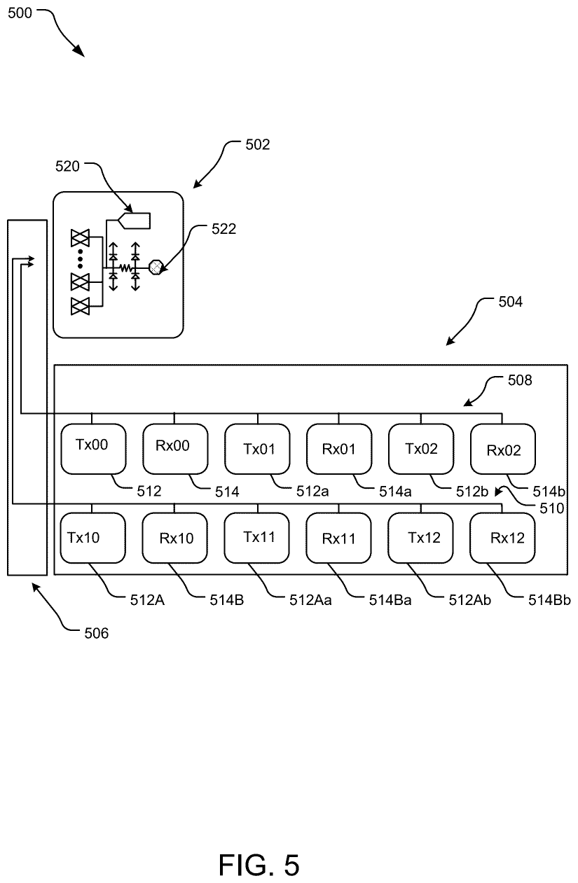

Now referring to FIG. 5, it illustrates an alternative implementation of a chip testing system 500 using an analog to digital (ADC) converter for wafer sorting. Specifically, the chip testing system 500 includes a wafer 504 having a number of Tx macros and Rx macros 512, 514. Specifically, in the illustrated implementation, the wafer 504 includes Tx macros Tx00, Tx10, Tx01, Tx11, Tx02, and Tx12 as well as Rx macros Rx00, Rx10, Rx01, Rx11, Rx02, and Rx12. Each of these macros 512, 514 may have various analog components that generate analog voltages that may need to be measured and managed for proper functioning of the macros on the wafer. For example, in some implementations, these macros 512, 514 may have as much as twenty (20) percentage of components that are analog, and their voltages need to be compliant to one or more specifications for proper functioning of the wafer 504.

As illustrated the analog signals may be communicated over analog test buses (ATB) 508, 510 via a PHY level ATB channel 506 to a bring-up board 502 that can be used to debug circuits and issues with the wafer 504 during bring-up of the wafer 504. The bring-up board 502 may have an analog to digital converter (ADC) 520 and an ATB pad 522 that may be used to test the voltages communicated over the (ATB) 508, 510. Specifically, the voltages on the wafter 504 communicated to the bring-up board 502 are converted into digital voltages by the ADC 520 and can be measured in parallel via the ATB pad 522. In one implementation, the ATB pad 522 can be used to measure critical voltage levels such as voltage biases, voltage reference, etc. The measured voltages may be evaluated to determine if a part of the wafer 504 is out of spec out of specification. If so, that part can be discarded or settings on the wafer may be trimmed until wafer 504 meets the specification. For example, trimming the parts to bring the wafer 504 within specification may requires fusing as part of bring-up sequence for the wafter 504. Specifically, during wafer sort and packaged part testing the ATB method (using analog voltages) may be deemed too expensive or prohibitive. Therefore, the ADC allows an alternative way to measure the analog voltages via an on-chip ADC and communication to registers that can be read out digitally.

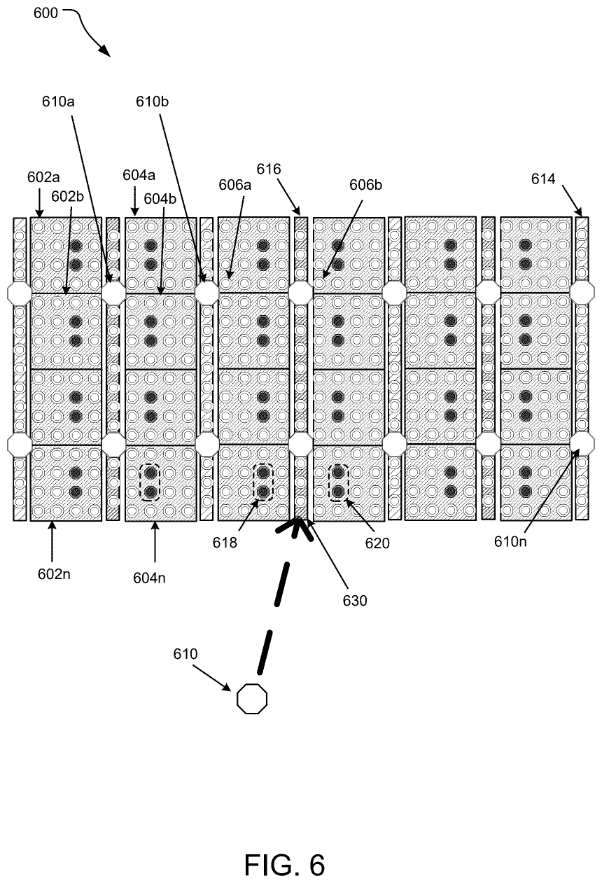

FIG. 6 illustrates a layout of a wafer 600 using one or more sacrificial pads that can be used for wafer sort. Specifically, the wafer 600 may include a number of sacrificial pads 610a, 610b, . . . 610n (referred to herein as sacrificial pads 610) that are placed in between various macros, including transmit (Tx) macros 602 (602a, 602b, . . . ) and receive (Rx) macros 604 (604a, 604b, . . . ). As illustrated the Tx macros 602 may include Tx clock bumps 618 and the Rx macros 604 may include the Rx clock bumps 620.

The sacrificial pads 610 may be located on power supply (VSS) columns 614 and on ground columns (VDD) 616 such that they do not overlap any of the lanes 606 (606a, 606b, . . . ) on the macros 602, 604. Specifically, sacrificial pads 610 are placed at the ends of the VSS columns 614 and on the VDD 616 in a common area 630.

A device disclosed herein includes a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer.

A die-to-die testing system disclosed herein includes a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer.

A system on chip disclosed herein includes a wafer including a plurality of Tx macros, each of the Tx macro including a plurality of transmit lanes; a pseudorandom bit sequence (PRBS) generator configured on one of the Tx macros, the PRBS generator configured to generate a PRBS serial signal; a transmit data path to transmit the PRBS signal to one or more of a plurality of transmit lanes of a transmitter (Tx) macro; and a logic device to compare the output from the one or more of the plurality of transmit lanes to generate an error flag, wherein a positive value of the error flag indicates a manufacturing defect on the wafer.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the structures disclosed herein, and do not create limitations, particularly as to the position, orientation, or use of such structures. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other. The example drawings are for purposes of illustration only and the dimensions, positions, order and relative sizes reflected in the drawings attached hereto may vary.

The above specification, examples and data provide a complete description of the structure and use of example embodiments of the invention as defined in the claims. Although various embodiments of the claimed invention have been described above with a certain degree of particularity, or with reference to one or more individual embodiments, other embodiments using different combinations of elements and structures disclosed herein are contemplated, as other iterations can be determined based upon the teachings of the present disclosure. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A device, comprising:
a wafer including a plurality of Tx macros, each of the Tx macro including a plurality of transmit lanes;
a pseudorandom bit sequence (PRBS) generator configured on one of the Tx macros, the PRBS generator configured to generate a PRBS serial signal;
a transmit data path to transmit the PRBS signal to one or more of a plurality of transmit lanes of a transmitter (Tx) macro; and
a logic device to compare the output from the one or more of the plurality of transmit lanes to generate an error flag;
wherein a positive value of the error flag indicates a manufacturing defect on the wafer.

2. The device of claim 1, wherein the logic device includes a plurality of XOR gates configured to compare output from the plurality of transmit lanes of a transmitter (Tx) macro.

3. The device of claim 2, wherein each of the plurality of XOR gates is configured to compare the output from adjacent of the plurality of transmit lanes of a transmitter (Tx) macro.

4. The device of claim 1, wherein the logic device generates output signal that is based on a 2-bit XOR truth table.

5. The device of claim 1, wherein the logic device includes a plurality of XOR gates, each of the \plurality of XOR gates configured to receive input from adjacent of the plurality of transmit lanes of a transmitter (Tx) macro and from the PRBS generator.

6. The device of claim 1, wherein the logic device generates output signal that is based on a 3-bit XOR truth table.

7. The device of claim 1, further comprising an Rx data path wherein the PRBS generator is configured to drive one or more of a plurality of receive (Rx) lanes of an Rx macro.

8. The device of claim 7, wherein the PRBS generator is implemented using an odd data path wherein the PRBS generator is timed at only a rising edge of the clock signal.

9. The device of claim 7, wherein the PRBS generator is implemented using a unit interval (UI) method wherein the PRBS generator is timed at a positive edge and a negative edge of a clock signal.

10. A die-to-die testing system, comprising:
a wafer including a plurality of Tx macros, each of the Tx macro including a plurality of transmit lanes;
a pseudorandom bit sequence (PRBS) generator configured on one of the Tx macros, the PRBS generator configured to generate a PRBS serial signal;
a transmit data path to transmit the PRBS signal to one or more of a plurality of transmit lanes of a transmitter (Tx) macro; and
a logic device to compare the output from the one or more of the plurality of transmit lanes to generate an error flag;
wherein a positive value of the error flag indicates a manufacturing defect on the wafer.

11. The die-to-die testing system of claim 10, further comprising an Rx data path wherein the PRBS generator is configured to drive one or more of a plurality of receive (Rx) lanes of an Rx macro.

12. The die-to-die testing system of claim 11, wherein the PRBS generator is implemented using an odd data path wherein the PRBS generator is timed at only a rising edge of the clock signal.

13. The die-to-die testing system of claim 11, wherein the PRBS generator is implemented using a unit interval (UI) method wherein the PRBS generator is timed at a positive edge and a negative edge of a clock signal.

14. The die-to-die testing system of claim 10, wherein the logic device includes a plurality of XOR gates configured to compare output from the plurality of transmit lanes of a transmitter (Tx) macro.

15. The die-to-die testing system of claim 10, wherein each of the plurality of XOR gates is configured to compare the output from adjacent of the plurality of transmit lanes of a transmitter (Tx) macro.

16. A system on chip, comprising:
a wafer including a plurality of Tx macros, each of the Tx macro including a plurality of transmit lanes;
a pseudorandom bit sequence (PRBS) generator configured on one of the Tx macros, the PRBS generator configured to generate a PRBS serial signal;
a transmit data path to transmit the PRBS signal to one or more of a plurality of transmit lanes of a transmitter (Tx) macro; and
a logic device to compare the output from the one or more of the plurality of transmit lanes to generate an error flag;
wherein a positive value of the error flag indicates a manufacturing defect on the wafer.

17. The system on chip of claim 16, wherein the logic device includes a plurality of XOR gates configured to compare output from the plurality of transmit lanes of a transmitter (Tx) macro.

18. The system on chip of claim 17, wherein each of the plurality of XOR gates is configured to compare the output from adjacent of the plurality of transmit lanes of a transmitter (Tx) macro.

19. The system on chip of claim 16, wherein the logic device generates output signal that is based on a 2-bit XOR truth table.

20. The system on chip of claim 16, wherein the logic device includes a plurality of XOR gates, each of the plurality of XOR gates configured to receive input from adjacent of the plurality of transmit lanes of a transmitter (Tx) macro and from the PRBS generator.
